(19) United States
(12) Patent Application Publication
(10) Pub. No.: US 2013/0088838 A1
(43) Pub. Date: Apr. 11, 2013

(54) DIE PACKAGE, METHOD OF MANUFACTURING THE SAME, AND SYSTEMS INCLUDING THE SAME

(71) Applicants: JAE JUN LEE, Seongnam-si (KR); Jeong Hyeon Cho, Hwaseong-si (KR); Baek Kyu Choi, Yongin-si (KR); Sun Won Kang, Seongnam-si (KR); Jung Joon Lee, Seoul (KR)

(72) Inventors: JAE JUN LEE, Seongnam-si (KR); Jeong Hyeon Cho, Hwaseong-si (KR); Baek Kyu Choi, Yongin-si (KR); Sun Won Kang, Seongnam-si (KR); Jung Joon Lee, Seoul (KR)

(21) Appl. No.: 13/567,388

(22) Filed: Aug. 6, 2012

(30) Foreign Application Priority Data
Oct. 10, 2011 (KR) 10-2011-0103133

(51) Int. Cl. H05K 7/00; H01L 21/50; H01L 23/50

(52) U.S. Cl. 361/728; 257/777; 438/107; 257/E23.079; 257/E21.502

(57) ABSTRACT

A die package includes a substrate, a die mounted on the substrate, and a ZQ resistor disposed in the die package and connected to the substrate and the die. The ZQ resistor may be used to calibrate impedance of the die.

### CROSS-REFERENCE TO RELATED APPLICATIONS

This application claims priority under 35 U.S.C. §119 to Korean Patent Application No. 10-2011-0103133, filed on Oct. 10, 2011, the disclosure of which is incorporated by reference herein in its entirety.

### TECHNICAL FIELD

Exemplary embodiments of the inventive concept relate to circuit packaging, and more particularly, to a die package that may improve signal integrity and power integrity, a method of manufacturing the same, and systems including the same.

### DISCUSSION OF THE RELATED ART

Semiconductor packaging is typically the last process performed when manufacturing semiconductor devices. Semiconductor packaging is a process of connecting each semiconductor chip within a die package to electrical wiring to enable the chips to communicate with external devices, and hermetically sealing and packaging the semiconductor chips to enable them to withstand external impact such as, for example, physical or chemical impact.

As the density of semiconductor chips in a die package increases, the size of the die package decreases. As the size of the die package decreases, less components may fit within the die package. For example, die packages that utilize a ZQ resistor for calibration purposes typically connect to an external ZQ resistor via a ZQ pin disposed in the die, rather than including the ZQ resistor within the die package itself. Such a configuration may result in reduced signal integrity and power integrity of the semiconductor device.

### SUMMARY

According to an exemplary embodiment of the inventive concept, there is provided a die package including a substrate, a first die mounted on the substrate, and a first resistor connected between the substrate and the first die. When the first die is a memory device, the first resistor is a ZQ resistor used to calibrate impedance of an output driver of the memory device. The memory device may be a volatile memory or a non-volatile memory. The die package does not include a ZQ pin.

The first resistor may be embedded in the substrate. The first resistor may be a thick film resistor or a thin film resistor. The thick film resistor may be a surface mount device (SMD) resistor. The die package may further include a second die mounted on the first die, and a second resistor connected between the substrate and the second die.

According to an exemplary embodiment of the inventive concept, there is provided a memory module including a module board and the above-described die package, which is mounted on the module board. The memory module may be a dual in-line memory module (DIMM), a dual in-line package (DIP) memory module, a single in-line pin package (SIPP) memory module, a single in-line memory module (SIMM), or a small outline DIMM (SO-DIMM).

According to an exemplary embodiment of the inventive concept, there is provided a memory system including the above-described memory module and a memory controller configured to control the memory module.

According to an exemplary embodiment of the inventive concept, a memory system includes the above-described die package and a memory controller configured to control a data processing operation of the die package.

According to an exemplary embodiment of the inventive concept, a method of manufacturing a die package includes mounting a die on a substrate, connecting a resistor between the die and the substrate, and packaging the die and the resistor. When the die is a memory device, the resistor is a ZQ resistor used to calibrate impedance of an output driver of the memory device.

According to an exemplary embodiment of the inventive concept, a die package includes a substrate, a first die mounted on the substrate, and a first ZQ resistor disposed in the die package and connected to the substrate and the first die. The first ZQ resistor is configured to calibrate an impedance of the first die.

According to an exemplary embodiment of the inventive concept, a method of manufacturing a die package includes mounting a first die on a substrate, connecting a first ZQ resistor to the first die and the substrate, and forming an encapsulation layer on the first die and the first ZQ resistor. The first ZQ resistor is configured to calibrate an impedance of the first die.

According to an exemplary embodiment of the inventive concept, a die package includes a substrate, a first die mounted on the substrate, an interposer disposed on an upper surface of the first die, and a first ZQ resistor disposed in the die package and connected to the substrate and the upper surface of the first die in an area between an end of the interposer and an end of the first die. The first ZQ resistor is configured to calibrate an impedance of the first die.

### BRIEF DESCRIPTION OF THE DRAWINGS

The above and other features of the inventive concept will become more apparent by describing in detail exemplary embodiments thereof with reference to the accompanying drawings, in which:

FIG. 1 is a cross-sectional view of a die package, according to an exemplary embodiment of the inventive concept;

FIG. 2 is a cross-sectional view of a die package, according to an exemplary embodiment of the inventive concept;

FIG. 3 is a cross-sectional view of a die package, according to an exemplary embodiment of the inventive concept;

FIG. 4 is a block diagram of a memory device included in the die illustrated in FIG. 1, according to an exemplary embodiment of the inventive concept;

FIG. 5 is a flowchart of a method of manufacturing the die package illustrated in FIG. 1, according to an exemplary embodiment of the inventive concept;

FIG. 6 is a diagram of a memory system including the die package illustrated in FIG. 1, 2 or 3, according to exemplary embodiments of the inventive concept;

FIG. 7 is a diagram of a memory system including the die package illustrated in FIG. 1, 2 or 3, according to exemplary embodiments of the inventive concept;

FIG. 8 is a diagram of a memory system including the die package illustrated in FIG. 1, 2 or 3, according to exemplary embodiments of the inventive concept;

FIG. 9 is a diagram of a memory system including the die package illustrated in FIG. 1, 2 or 3, according to exemplary embodiments of the inventive concept;

FIG. 10 is a diagram of a memory system including the die package illustrated in FIG. 1, 2 or 3, according to exemplary embodiments of the inventive concept;

FIG. 11 is a diagram of a memory system including the die package illustrated in FIG. 1, 2 or 3, according to exemplary embodiments of the inventive concept;

FIG. 12 is a diagram of a memory system including the die package illustrated in FIG. 1, 2 or 3, according to exemplary embodiments of the inventive concept; and

FIG. 13 is a diagram of a data processing system including the memory system illustrated in FIG. 12, according to an exemplary embodiment of the inventive concept.

### DETAILED DESCRIPTION OF THE EXEMPLARY EMBODIMENTS

Exemplary embodiments of the inventive concept will be described more fully hereinafter with reference to the accompanying drawings. Like reference numerals may refer to like elements throughout the accompanying drawings.

It will be understood that when an element is referred to as being “connected” or “coupled” to another element, it can be directly connected or coupled to the other element or intervening elements may be present.

It will be further understood that, although the terms first, second, etc. may be used herein to describe various elements, these elements should not be limited by these terms. These terms are only used to distinguish one element from another. For example, a first signal could be termed a second signal, and, similarly, a second signal could be termed a first signal without departing from the teachings of the inventive concept.

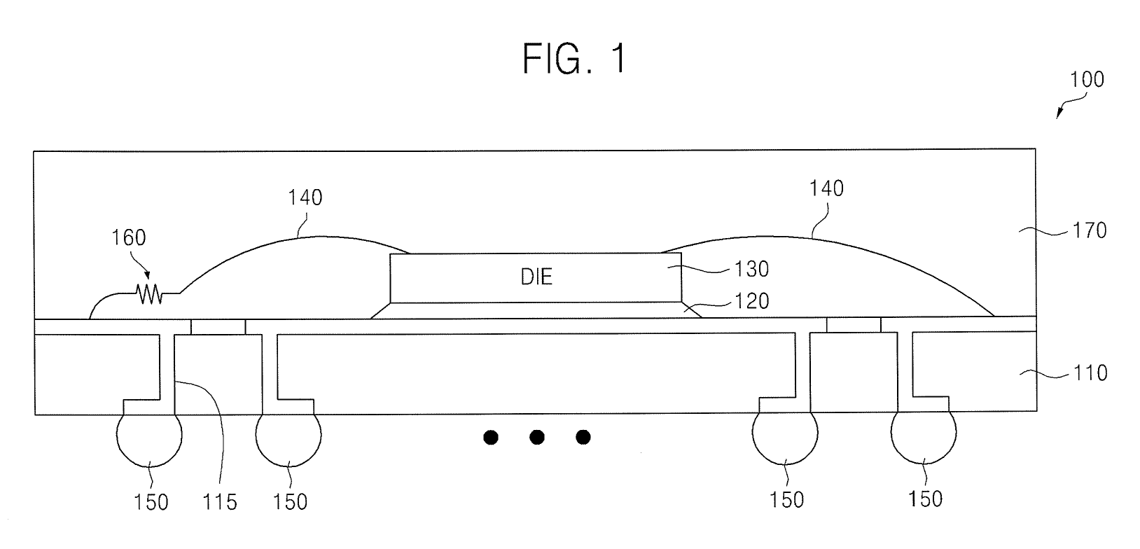

FIG. 1 is a cross-sectional view of a die package 100, according to an exemplary embodiment of the inventive concept. Referring to FIG. 1, the die package 100 includes a substrate 110, an adhesive means 120, a die 130, a plurality of solder balls 150, and a resistor 160.

The die package 100 in FIG. 1 is a ball grid array (BGA), however, the die package 100 is not limited thereto. For example, the die package 100 may be a package on package (PoP), a chip scale package (CSP), a plastic leaded chip carrier (PLCC), a plastic dual in-line package (PDIP), a chip on board (COB), a ceramic dual in-line package (CERDIP), a plastic metric quad flat pack (MQFP), a thin quad flat pack (TQFP), a small outline integrated circuit (SOIC), a shrink small outline package (SSOP), a thin small outline package (TSOP), a system in package (SIP), a multi-chip package (MCP), a wafer-level package (WLP), or a wafer-level processed stack package (WSP).

The substrate 110 may be implemented using, for example, a semiconductor or an electrical insulator. The electrical insulator may be made using a material such as, for example, silicon oxide or aluminum oxide.

The adhesive means 120 attaches the die 130 to the substrate 110. The adhesive means 120 may be, for example, an adhesive paste or an adhesive tape.

The die 130 is mounted on the substrate 110 using the adhesive means 120. As described above, the die 130 may be referred to as a chip or an integrated circuit (IC). The die 130 may be implemented as, for example, a processor, a memory controller, or a memory device.

The memory device may be volatile memory such as, for example, dynamic random access memory (DRAM), static RAM (SRAM), thyristor RAM (T-RAM), zero capacitor RAM (Z-RAM), or twin transistor RAM (TTRAM).

Alternatively, the memory device may be non-volatile memory such as, for example, electrically erasable programmable read-only memory (EEPROM), flash memory, magnetic RAM (MRAM), spin-transfer torque MRAM, conductive bridging RAM (CBRAM), ferroelectric RAM (FeRAM), phase change RAM (PRAM), resistive RAM (RRAM or ReRAM), nanotube RRAM, polymer RAM (PoRAM), nano floating gate memory (NFGM), holographic memory, molecular electronics memory device, or insulator resistance change memory.

A bonding wire 140 electrically connects the die 130 and the substrate 110. The bonding wire 140 may be made using, for example, aluminum, copper, or gold. Each of the solder balls 150 and the bonding wire 140 are electrically connected through a via 115.

The resistor 160 within the die package 100 is connected between the substrate 110 and the bonding wire 140. The resistor 160 may have a resistance value of about 20 Q, however, exemplary embodiments of the inventive concept are not limited thereto. The resistor 160 may be, for example, a thick film resistor (e.g., a surface mount device (SMD) resistor) or a thin film resistor.

When the die 130 includes a memory device, the resistor 160 may be a ZQ resistor. A ZQ resistor may be used for ZQ calibration, which may be performed to calibrate the impedance of the memory device (e.g., the impedance of an output driver of the memory device).

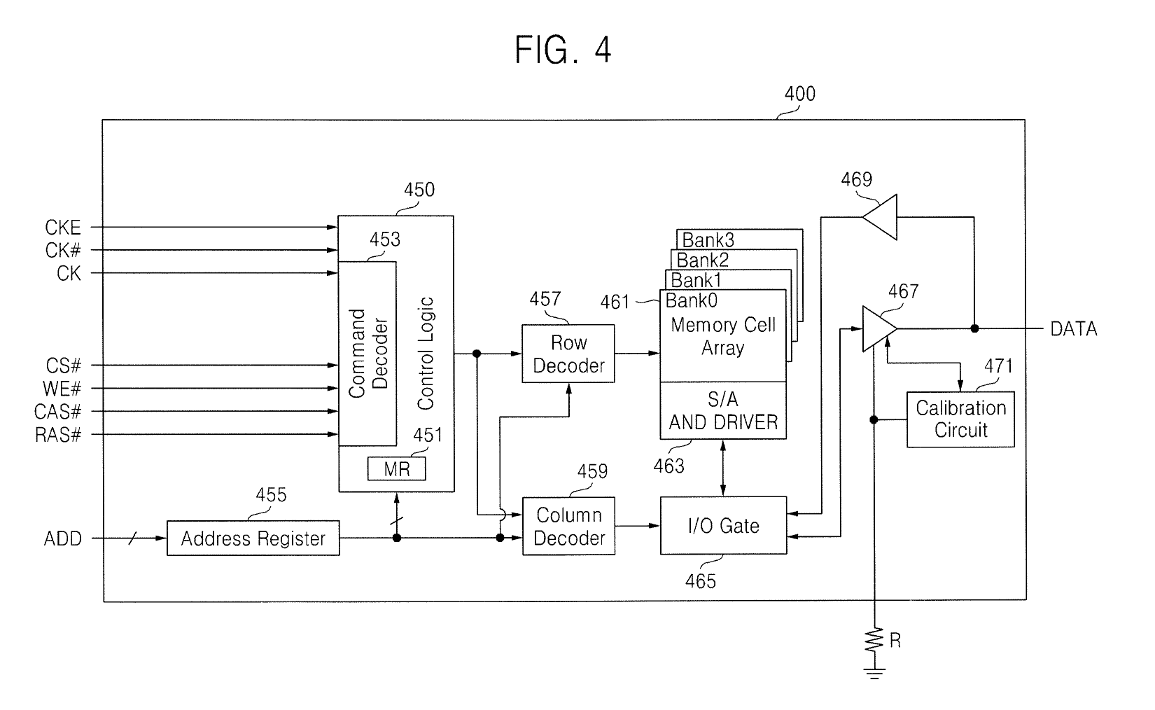

In exemplary embodiments of the inventive concept, the resistor 160 used as the ZQ resistor is embedded in the die package 100. The ZQ resistor will be further described with reference to FIG. 4. Since the resistor 160 is embedded in the die package 100, the number of solder balls 150 utilized in the die package 100 may be reduced. In an exemplary embodiment, one of the solder balls 150 may be used for a different purpose than the other solder balls 150. For example, one of the solder balls 150 may be used as a power ball connected to a power supply, or a ground ball connected to ground. When one of the solder balls 150 is used as the power ball or the ground ball, signal integrity and/or power integrity may be improved.

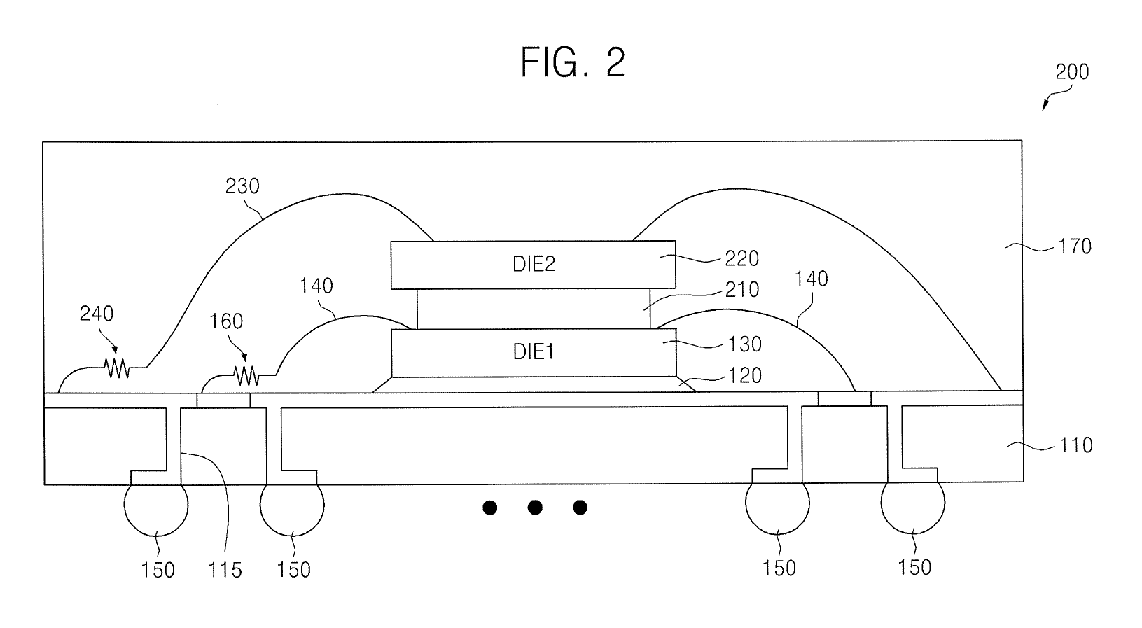

FIG. 2 is a cross-sectional view of a die package 200, according to an exemplary embodiment of the inventive concept. The die package 200 includes the substrate 110, the adhesive means 120, a plurality of dies 130 and 220, a plurality of the solder balls 150, a plurality of bonding wires 140 and 230, and a plurality of resistors 160 and 240.

An interposer 210 is positioned between the first die 130 and the second die 220, and may allow sufficient clearance for wire bonding. The interposer 210 may be made using, for example, silicon.

The second die 220 is mounted on the interposer 210. The second die 220 may be implemented as, for example, a processor, a memory controller, or a memory device. When the first die 130 is a volatile memory (e.g., DRAM), the second die 220 may also be a volatile memory (e.g., DRAM). Alternatively, when the first die 130 is a memory controller, the second die 220 may be a memory device.

The first and second dies 130 and 220 may have the same or different sizes. The second resistor 240 within the die package 200 is electrically connected between the substrate 110 and the bonding wire 230. The second resistor 240 may function as a ZQ resistor.

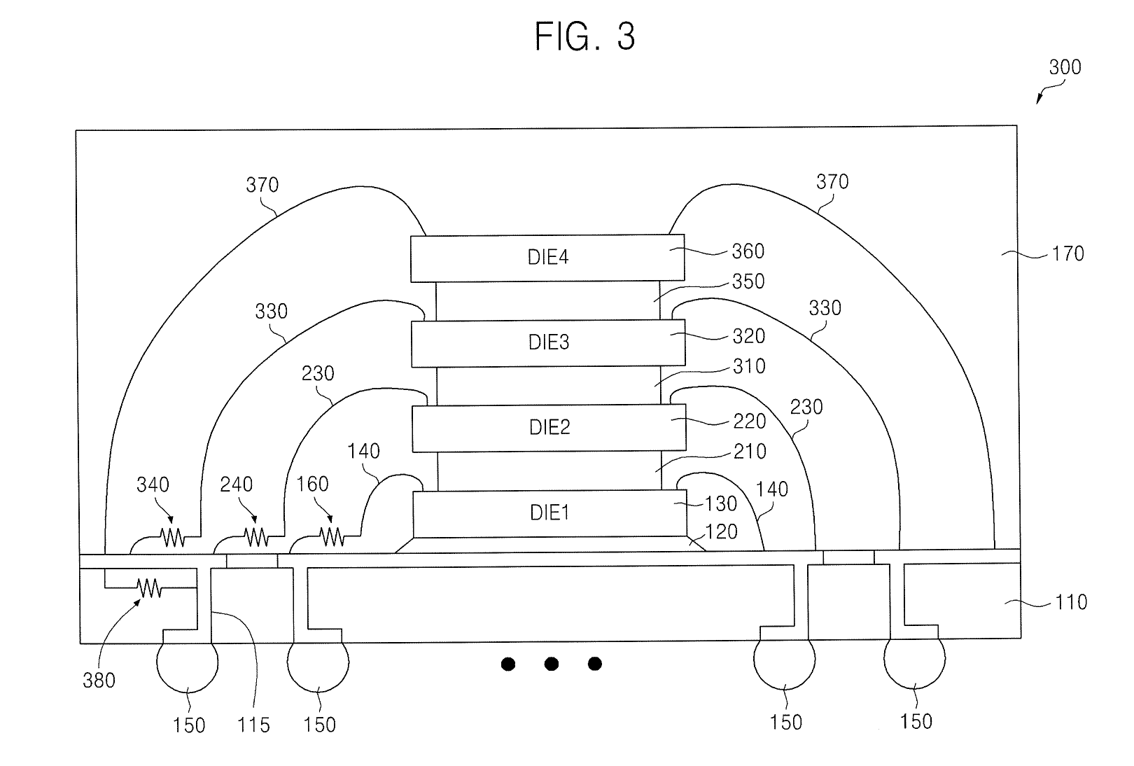

FIG. 3 is a cross-sectional view of a die package 300, according to an exemplary embodiment of the inventive concept. The die package 300 includes the substrate 110, the adhesive means 120, a plurality of dies 130, 220, 320 and 360, a plurality of the solder balls 150, a plurality of bonding wires 140, 230, 330 and 370, and a plurality of resistors 160, 240, 340 and 380.

Interposers 210, 310 and 350 are positioned between the adjacent dies, (e.g., 130 and 220, 220 and 320, and 320 and 360), and allow sufficient clearance for wire bonding.

The third die 320 is mounted on the second interposer 310, and the fourth die 360 is mounted on the third interposer 350. Each of the third and fourth dies 320 and 360 may be implemented as, for example, a processor, a memory controller, or a memory device. The dies 130, 220, 320 and 360 may include different ICs from one another. The third resistor 340 is connected between the substrate 110 and a bonding wire 330. The fourth resistor 380 is embedded in the substrate 110.

FIG. 4 is a block diagram of a memory device 400 included in the die 130 illustrated in FIG. 1, according to an exemplary embodiment. The memory device 400 may be, for example, a dual data rate (DDR) DRAM.

Referring to FIGS. 1 and 4, the memory device 400 includes a control logic 450, an address register 455, a row decoder 457, a column decoder 459, a memory cell array 461 including a plurality of banks Bank0 through Bank3, a sense amplifier (S/A) and driver 463, an input/output (I/O) gate 465, an output driver 467, an input buffer 469, and a calibration circuit 471.

The control logic 450 outputs a plurality of signals that control the row decoder 457 and the column decoder 459 in response to a plurality of control signals CKE, CK #, CK, CS #, WE #, CAS #, and RAS #.

The symbol “#” denotes low activation. The clock enable signal CKE, the inverted clock signal CK #, and the clock signal CK may be output from a clock driver. The chip select signal CS #, the write enable signal WE #, the column address strobe signal CAS #, and the row address strobe signal RAS # may be output from a memory controller.

The control logic 450 includes a mode register (MR) 451 and a command decoder 453. The MR 451 stores data used to control various operation modes of the memory device 400. The command decoder 453 decodes the control signals CS #, WE #, CAS #, and RAS #, and generates the signals used to control the row decoder 457 and the column decoder 459 according to a decoding result.

For example, when the control signals CS #, CAS #, and WE # are at a low level, and the control signal RAS # is at a high level, the command decoder 453 may generate a write command.

The address register 455 receives addresses ADD and transmits a row address among the addresses ADD to the row decoder 457, and a column address among the addresses ADD to the column decoder 459.

In response to a control signal output from the control logic 450, the row decoder 457 decodes the row address received from the address register 455, and selects and drives one of a plurality of word lines implemented in the memory cell array 461 according to a decoding result.

Each of the banks Bank0 through Bank3 includes a plurality of word lines, a plurality of bit lines, and a plurality of memory cells that store data.

During a read operation, the S/A and driver 463 senses and amplifies a voltage change in each of the bit lines, and transmits amplified signals to the I/O gate 465. During a write operation, the S/A and driver 463 writes signals output from the I/O gate 465 to the memory cell array 461.

In response to a control signal output from the control logic 450, the column decoder 459 decodes the column address received from the address register 455 and generates a plurality of column select signals according to a decoding result.

The I/O gate 465 transmits data output from the input buffer 469 to the S/A and driver 463 during the write operation, and transmits signals sensed and amplified by the S/A and driver 463 to the output driver 467 during the read operation. The output driver 467 outputs the data to the memory controller.

To increase data transmission efficiency, the impedance of the output driver 467 may be substantially the same as the impedance of a receiver of the memory controller.

Impedance matching between the output driver 467 and the receiver of the memory controller may allow data to be transmitted at a high frequency, and may reduce data distortion that can occur as a result of impedance mismatch.

Accordingly, to reduce the effect of impedance mismatch, the impedance of the output driver 467 may be configured to match the impedance of the receiver of the memory controller.

The calibration circuit 471 calibrates the impedance of the output driver 467. Accordingly, the calibration circuit 471 is connected to a ZQ resistor R, and carries out ZQ calibration using the ZQ resistor R. Each of the resistors 160, 240, 340 and 380 embedded in the die packages 100, 200 and 300 respectively illustrated in FIGS. 1 through 3 may function as the ZQ resistor R.

As described with reference to FIGS. 1 through 4, each of the resistors 160, 240, 340 and 380 functioning as the ZQ resistor R is embedded in the die package 100, 200 or 300. As a result signal and power integrity of the die packages 100, 200 and 300 may be improved.

According to an exemplary embodiment of the inventive concept, the die package 100, 200 or 300 includes at least one of the resistors 160, 240, 340 and 380 functioning as the ZQ resistor R. Since the ZQ resistor is disposed within the die package 100, 200 or 300 rather than external to the die package 100, 200 or 300, the die package 100, 200 or 300 does not include a ZQ pin configured to connect to an external ZQ resistor.

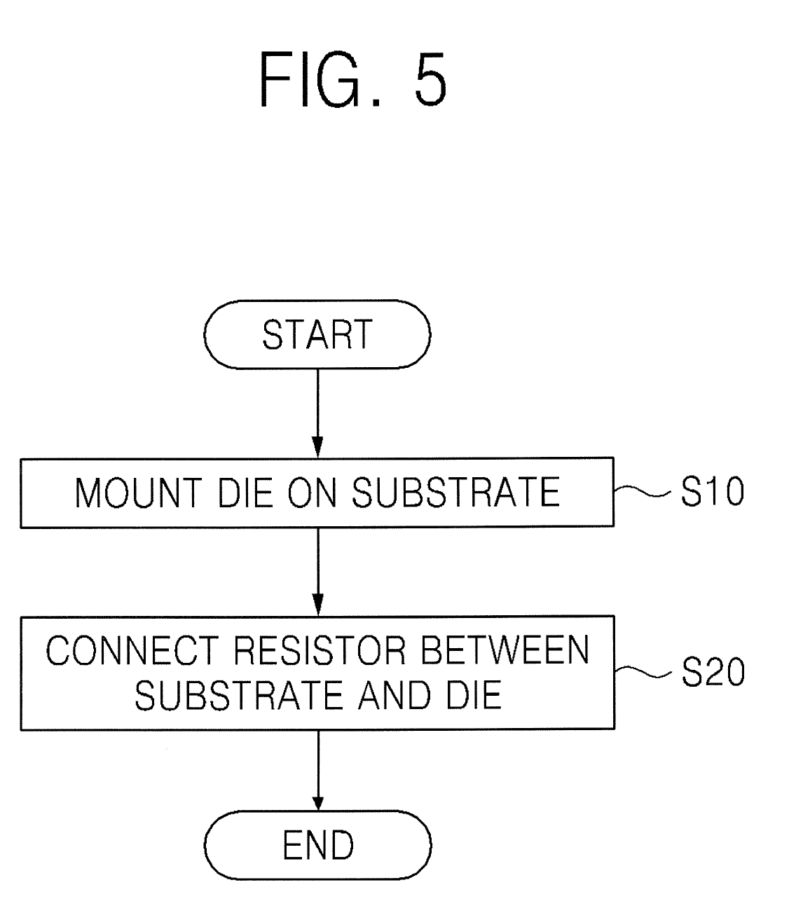

FIG. 5 is a flowchart of a method of manufacturing the die package 100 illustrated in FIG. 1, according to an exemplary embodiment of the inventive concept. Referring to FIGS. 1 and 5, the die 130 is mounted on the substrate 110 using the adhesive means 120 in operation S10. The resistor 160 is connected between the substrate 110 and the die 130 in operation S20. The adhesive means 120, the die 130, the bonding wires 140 and the resistor 160 are then packaged for protection. For example, an encapsulation layer 170 may be formed on the adhesive means 120, the die 130, the bonding wires 140, and the resistor 160.

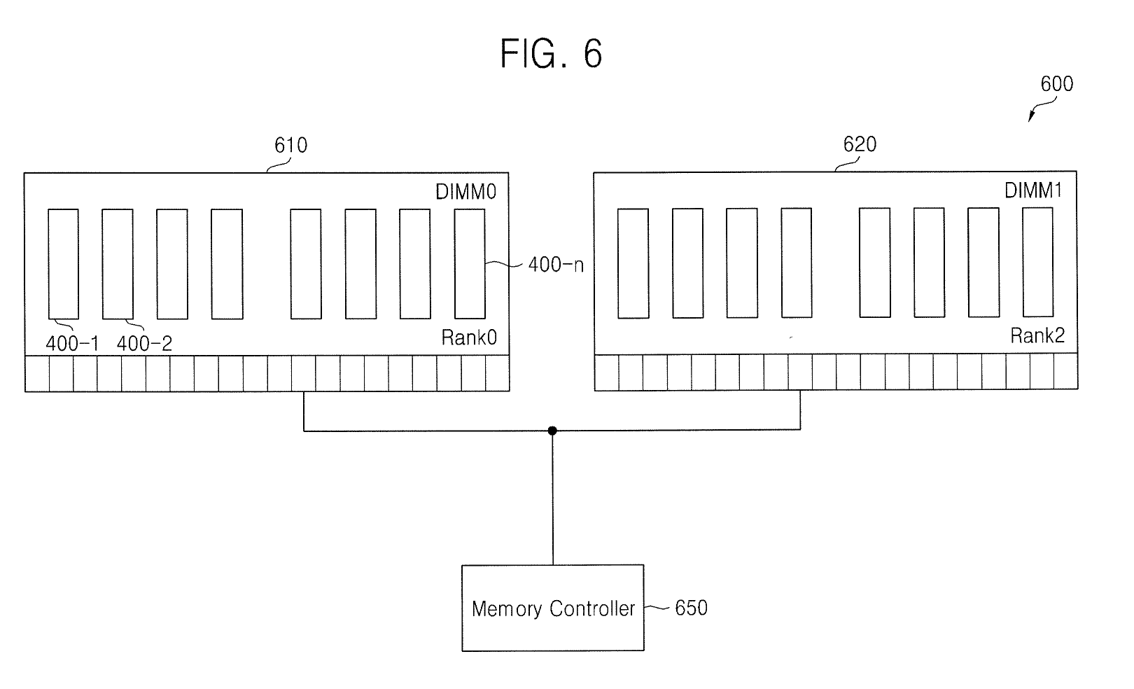

FIG. 6 is a diagram of a memory system 600 including the die package 100, 200 or 300 illustrated in FIG. 1, 2 or 3, according to exemplary embodiments of the inventive concept. Referring to FIGS. 1 through 3 and FIG. 6, the memory system 600 includes a plurality of memory modules 610 and 620 and a memory controller 650.

Each of the memory modules 610 and 620 may be implemented by, for example, a dual in-line memory module (DIMM), a dual in-line package (DIP) memory module, a single in-line pin package (SIPP) memory module, a single in-line memory module (SIMM), or a small outline DIMM (SO-DIMM).

Each of the memory modules 610 and 620 includes a plurality of ranks. Each of the ranks includes a plurality of memory devices 400-1 through 400-n. Each of the memory devices 400-1 through 400-n is implemented by the die package 100. The memory devices 400-1 through 400-n are mounted on a module board.

The memory controller 650 controls the memory modules 610 and 620.

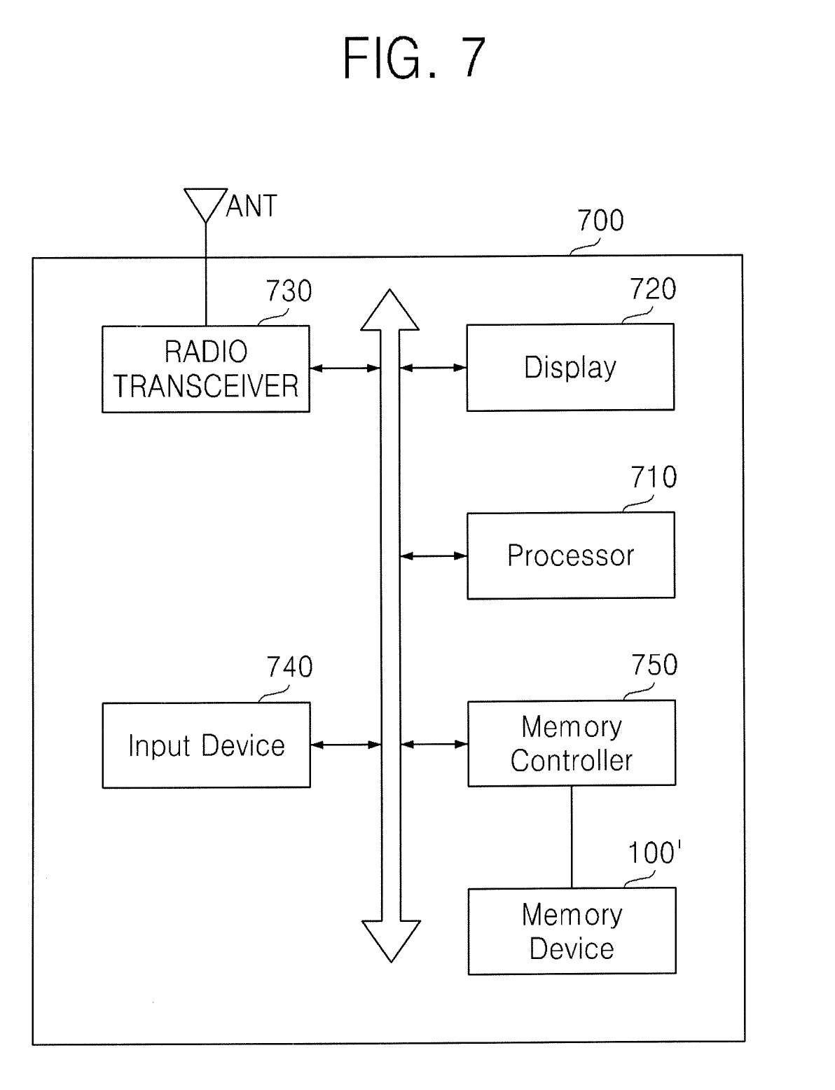

FIG. 7 is a diagram of a memory system 700 including the die package 100, 200 or 300 illustrated in FIG. 1, 2 or 3, according to exemplary embodiments of the inventive concept. Referring to FIG. 7, the memory system 700 may be implemented as, for example, a cellular phone, a smartphone, or a wireless Internet system. The memory system 700 includes a memory device 100′ and a memory controller 750 that controls a data processing operation (e.g., a program operation or a read operation) of the memory device 100′.

The memory device 100′ may be implemented by the die package 100, 200 or 300.

The memory controller 750 is controlled by a processor 710 that controls the overall operation of the memory system 700.

Data stored in the memory device 100′ may be displayed by a display 720 in response to the memory controller 750 controlled by the processor 710.

A radio transceiver 730 may transmit or receive radio signals through an antenna ANT. The radio transceiver 730 may convert radio signals received through the antenna ANT into signals that can be processed by the processor 710. Accordingly, the processor 710 may process the signals output from the radio transceiver 730 and store the processed signals in the memory device 100′ through the memory controller 750, or display the processed signals through the display 720. The radio transceiver 730 may convert signals output from the processor 710 into radio signals, and output the radio signals to an external device through the antenna ANT.

An input device 740 enables control signals that control the operation of the processor 710, or data to be processed by the processor 710, to be input to the memory system 700. The input device 740 may be, for example, a pointing device such as a touchpad or a computer mouse, a keypad, or a keyboard.

The processor 710 may control the display 720, and the display may display data output from the memory device 100′, radio signals output from the radio transceiver 730, or data output from the input device 740.

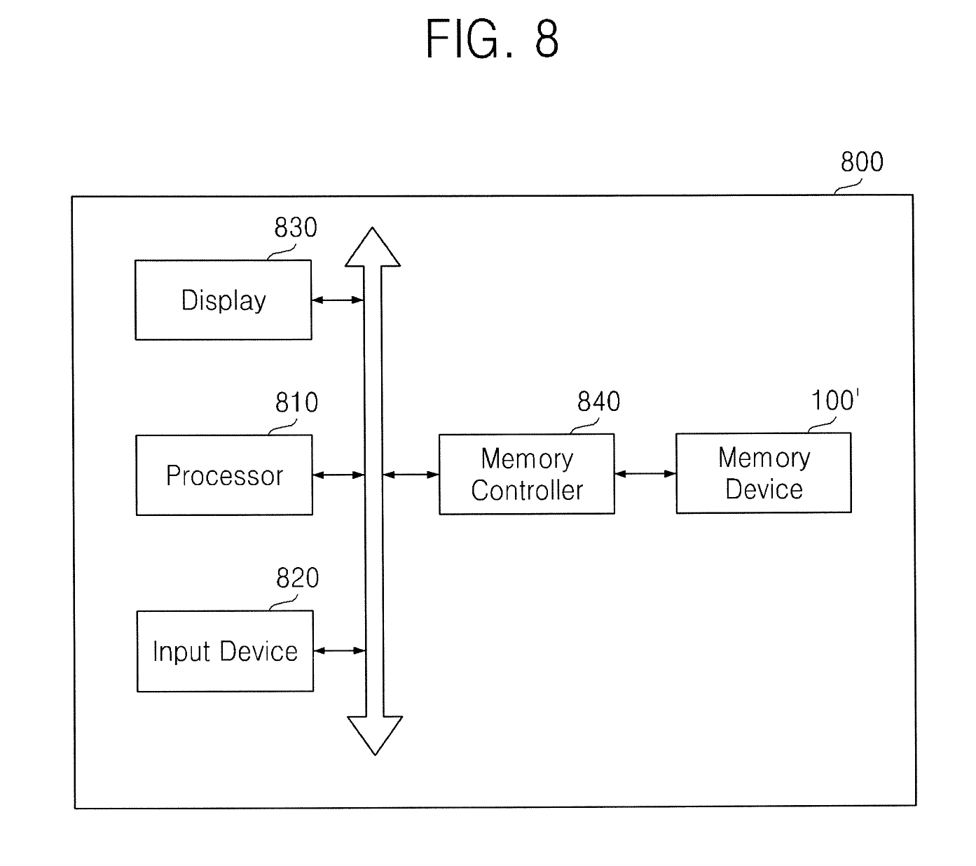

FIG. 8 is a diagram of a memory system 800 including the die package 100, 200 or 300 illustrated in FIG. 1, 2 or 3, according to exemplary embodiments of the inventive concept. Referring to FIGS. 1 through 3 and FIG. 8, the memory system 800 may be implemented as, for example, a personal computer (PC), a tablet PC, a netbook, an e-reader, a personal digital assistant (PDA), a portable multimedia player (PMP), an MP3 player, or an MP4 player. The memory system 800 includes a memory device 100′ and a memory controller 840 that controls the data processing operation of the memory device 100′.

The memory device 100′ may be implemented by the die package 100, 200 or 300.

The memory system 800 may also include a processor 810 that controls the overall operation of the memory system 800. The memory controller 840 is controlled by the processor 810.

The processor 810 may display data stored in the memory device 100′ through a display 830 according to an input signal generated in an input device 820. The input device 820 may be, for example, a pointing device such as a touchpad or a computer mouse, a keypad, or a keyboard.

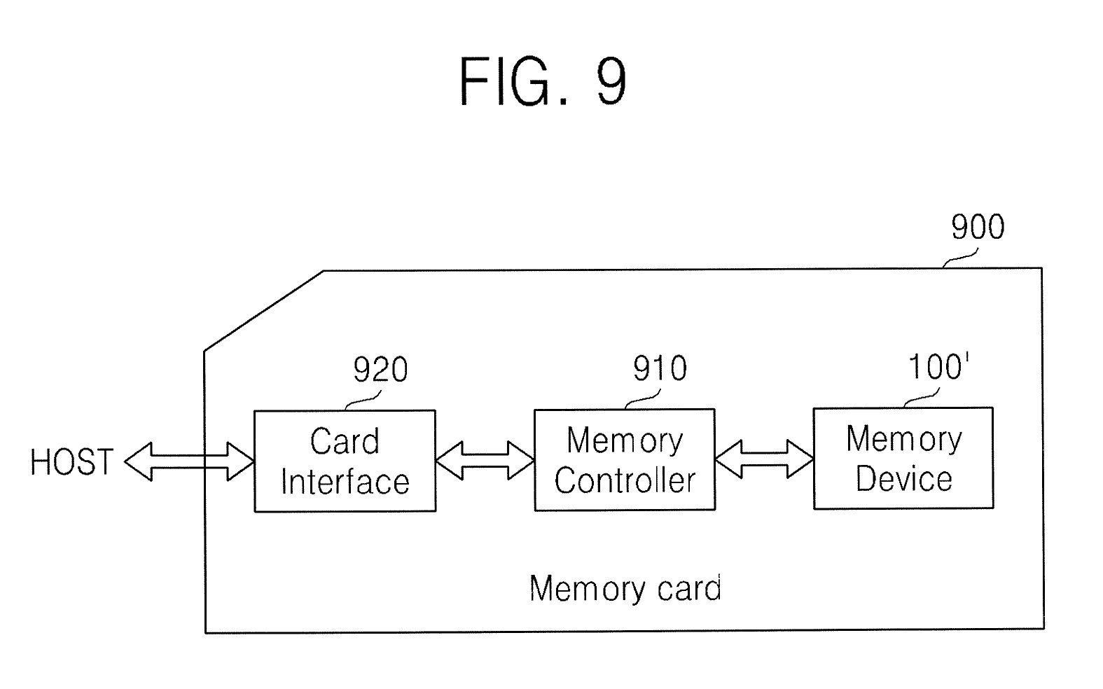

FIG. 9 is a diagram of a memory system 900 including the die package 100, 200 or 300 illustrated in FIG. 1, 2 or 3, according to exemplary embodiments of the inventive concept. Referring to FIGS. 1 through 3 and FIG. 9, the memory system 900 may be implemented as, for example, a memory card or a smart card. The memory system 900 includes a memory device 100′, a memory controller 910, and a card interface 920.

The memory device 100′ may be implemented by the die package 100, 200 or 300. The memory controller 910 may control data exchange between the memory device 100′ and the card interface 920.

The card interface 920 may be, for example, a secure digital (SD) card interface or a multi-media card (MMC) interface, however, the inventive concept is not limited thereto. The card interface 920 may interface a host and the memory controller 910 for data exchange according to a protocol of the host.

When the memory system 900 is connected with the host such as, for example, a computer, a digital camera, a digital audio player, a cellular phone, a video game console, or a digital set-top box, the host may transmit data to or receive data from the memory device 100′ through the card interface 920 and the memory controller 910.

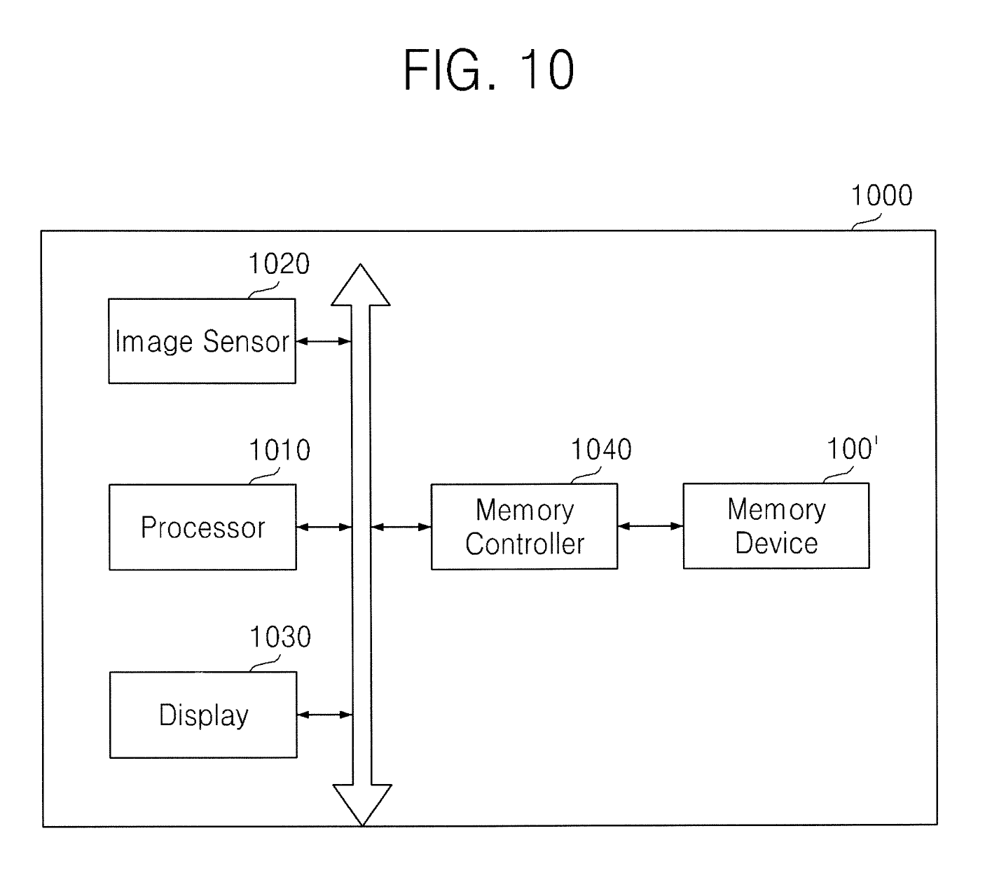

FIG. 10 is a diagram of a memory system 1000 including the die package 100, 200 or 300 illustrated in FIG. 1, 2 or 3, according to exemplary embodiments of the inventive concept. Referring to FIGS. 1 through 3 and FIG. 10, the memory system 1000 may be implemented as, for example, a digital camera or a portable device equipped with a digital camera.

The memory system 1000 includes a memory device 100′, a memory controller 1040 that controls the data processing operation of the memory device 100′, and a processor 1010 that controls the overall operation of the memory system 1000. The memory device 100′ may be implemented by the die package 100, 200 or 300.

An image sensor 1020 included in the memory system 1000 converts optical images into digital signals. The digital signals are stored in the memory device 100′ or displayed by a display 1030 under the control of the processor 1010. The digital signals stored in the memory device 100′ are displayed by the display 1030 under the control of the processor 1010.

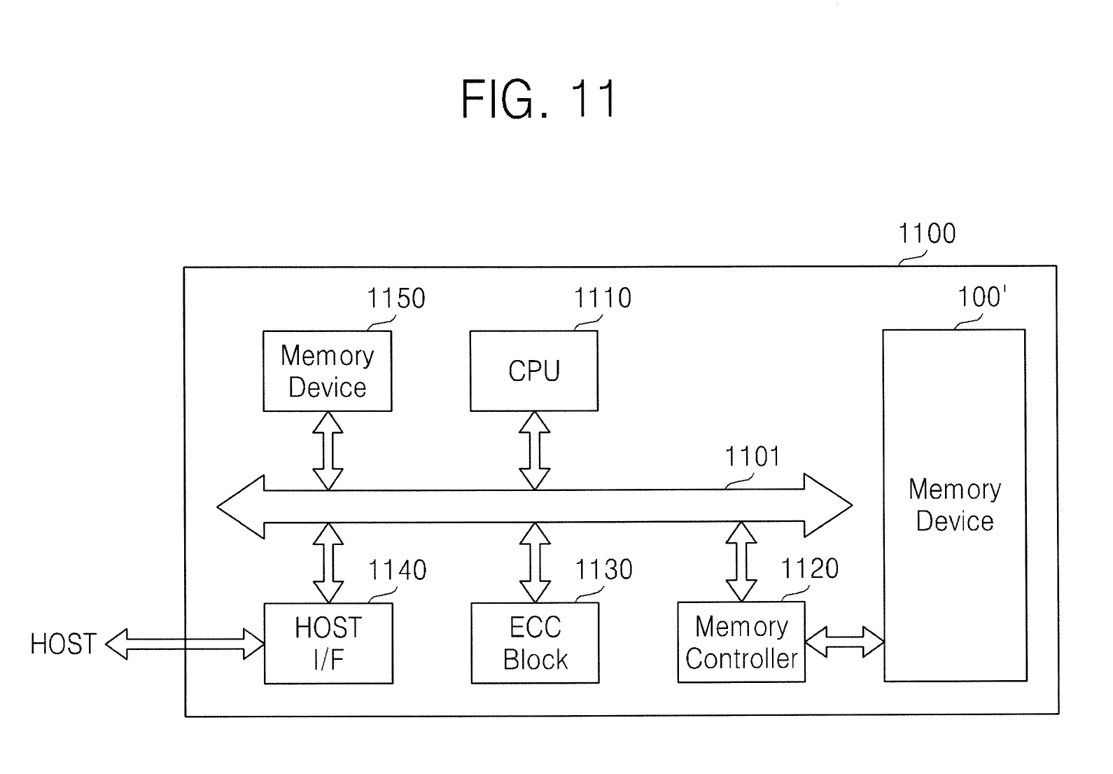

FIG. 11 is a diagram of a memory system 1100 including the die package 100, 200 or 300 illustrated in FIG. 1, 2 or 3, according to exemplary embodiments of the inventive concept. Referring to FIGS. 1 through 3 and FIG. 11, the memory system 1100 includes a memory device 100′, a memory controller 1120 that controls the operation of the memory device 100′, and a central processing unit (CPU) 1110 that controls the overall operation of the memory system 1100. The memory device 100′ may be implemented by the die package 100, 200 or 300.

The memory system 1100 also includes a memory 1150 that may be used as an operation memory of the CPU 1110. The memory 1150 may be, for example, a non-volatile memory such as a read-only memory (ROM) or a flash memory. A host connected with the memory system 1100 may transmit and receive data to and from the memory device 100′ through the memory controller 1120 and a host interface 1140, and the memory controller 1120 may function as a memory interface.

The memory system 1100 may also include an error correction code (ECC) block 1130.

The ECC block 1130 operates under the control of the CPU 1110, and may detect and correct errors in data read from the memory device 100′ through the memory controller 1120. The CPU 1110 may control data communication between the memory controller 1120, the ECC block 1130, the host interface 1140, and the memory 1150 through a bus 1101.

The memory system 1100 may be implemented as a universal serial bus (USB) memory drive or a memory stick.

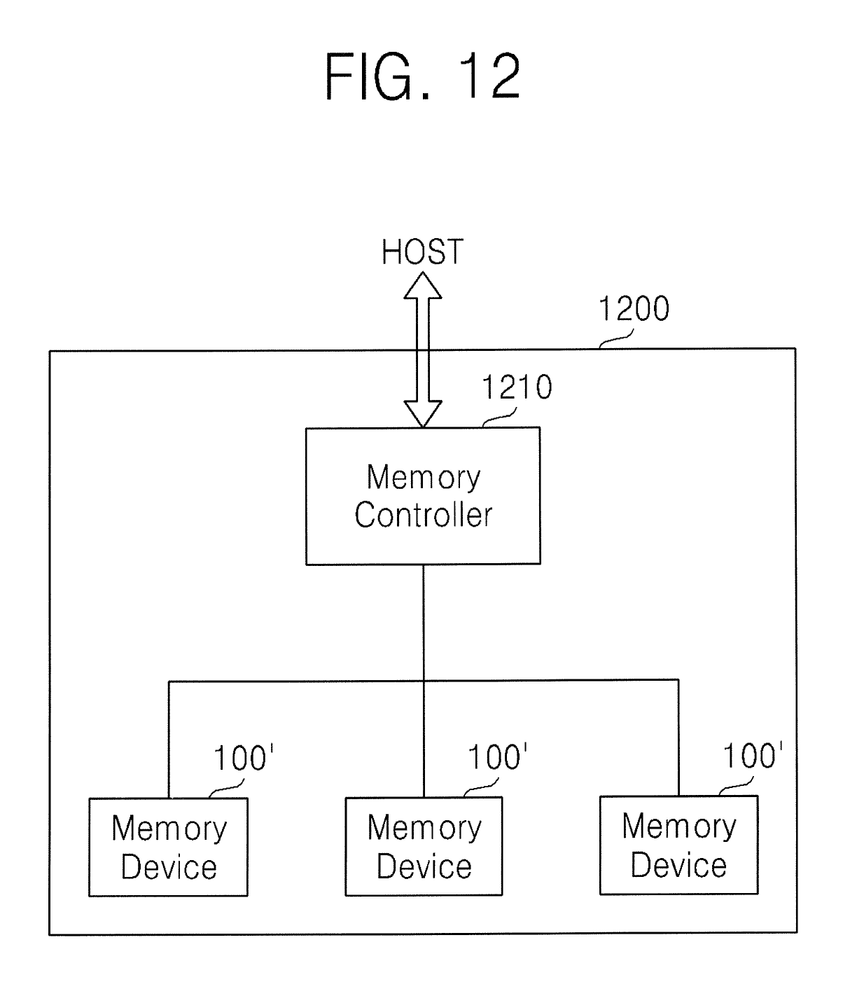

FIG. 12 is a diagram of a memory system 1200 including the die package 100, 200 or 300 illustrated in FIG. 1, 2 or 3, according to exemplary embodiments of the inventive concept. Referring to FIGS. 1 through 3 and FIG. 12, the memory system 1200 may be implemented as a data storage system such as, for example, a solid state drive (SSD). The memory system 1200 may include a plurality of memory devices 100′, and a memory controller 1210 that controls the data processing operation of the memory devices 100′. The memory system 1200 may be implemented as a memory module. Each of the memory devices 100′ may be implemented by the die package 100, 200 or 300.

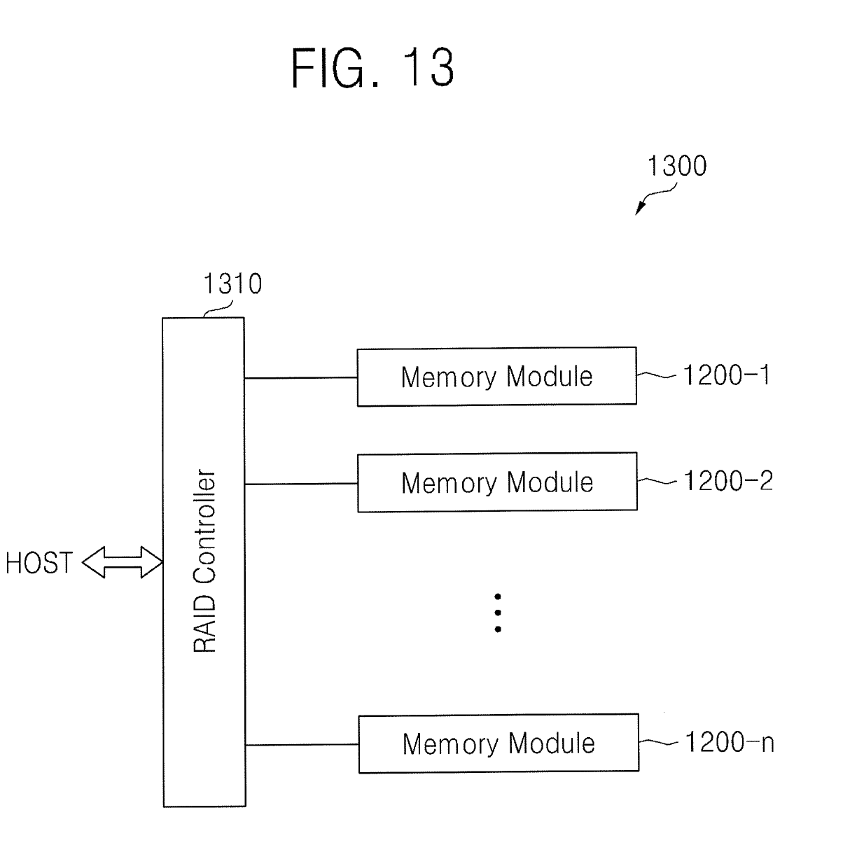

FIG. 13 is a diagram of a data processing system 1300 including the memory system 1200 illustrated in FIG. 12. Referring to FIGS. 12 and 13, the data processing system 1300 may be implemented as a redundant array of independent disks (RAID) system. The data processing system 1300 includes a RAID controller 1310 and a plurality of memory modules 1200-1 through 1200-n.

Each of the memory modules 1200-1 through 1200-n may be the memory system 1200 illustrated in FIG. 12. The memory modules 1200-1 through 1200-n may form a RAID array. The data processing system 1300 may be, for example, a PC or an SSD.

During a program operation, the RAID controller 1310 may transmit program data output from a host to one of the memory modules 1200-1 through 1200-n according to a RAID level in response to a program command received from the host. During a read operation, the RAID controller 1310 may transmit data read from one of the memory modules 1200-1 through 1200-n to the host in response to a read command received from the host.

As described above, according to exemplary embodiments of the inventive concept, a resistor is embedded in a die package, and as a result, signal integrity and power integrity may be improved. In addition, since the resistor is embedded in the die package, the number of solder balls used may be reduced.

While the inventive concept has been particularly shown and described with reference to the exemplary embodiments thereof, it will be understood by those of ordinary skill in the art that various changes in form and detail may be made therein without departing from the spirit and scope of the inventive concept as defined by the following claims.

1. A die package, comprising:
a substrate;
a first die mounted on the substrate; and
a first ZQ resistor disposed in the die package, and connected to the substrate and the first die,
wherein the first ZQ resistor is configured to calibrate an impedance of the first die.

2. The die package of claim 1, wherein the first die is a memory device.

3. The die package of claim 2, wherein the memory device comprises an output driver, and the first ZQ resistor is configured to calibrate an impedance of the output driver.

4. The die package of claim 2, wherein the memory device is a volatile memory or a non-volatile memory.

5. The die package of claim 1, wherein the die package does not comprise a ZQ pin.

6. The die package of claim 1, wherein the first ZQ resistor is embedded in the substrate.

7. The die package of claim 1, wherein the first ZQ resistor is a thick film resistor or a thin film resistor.

8. The die package of claim 7, wherein the thick film resistor is a surface mount device (SMD) resistor.

9. The die package of claim 1, further comprising:
a second die mounted on the first die; and
a second ZQ resistor connected to the substrate and the second die.

10. A memory module, comprising:
a module board; and
the die package of claim 1, wherein the die package is mounted on the module board.

11. The memory module of claim 10, wherein the memory module is one of a dual in-line memory module (DIMM), a dual in-line package (DIP) memory module, a single in-line pin package (SIPP) memory module, a single in-line memory module (SIMM), and a small outline DIMM (SO-DIMM).

12. A memory system, comprising:
the memory module of claim 10; and
a memory controller configured to control the memory module.

13. A memory system, comprising:
the die package of claim 1; and
a memory controller configured to control a data processing operation of the die package.

14. A method of manufacturing a die package, comprising:
mounting a first die on a substrate;
connecting a first ZQ resistor to the first die and the substrate, wherein the first ZQ resistor is configured to calibrate an impedance of the first die; and
forming an encapsulation layer on the first die and the first ZQ resistor.

15. The method of claim 14, further comprising embedding the first ZQ resistor in the substrate.

16. The method of claim 14, further comprising:
mounting a second die on the first die; and
connecting a second ZQ resistor to the second die and the substrate, wherein the second ZQ resistor is configured to calibrate an impedance of the second die.

17. The method of claim 14, further comprising:
forming a via in the substrate;
forming a solder ball on a lower surface of the substrate; and
connecting the first ZQ resistor to the solder ball through the via.

18.-20. (canceled)
